(19) United States
(12) Patent Application Publication
(10) Pub. No.: US 2021/0305197 A1
(43) Pub. Date: Sep. 30, 2021

(54) METHOD FOR CONNECTING COMPONENTS DURING PRODUCTION OF POWER ELECTRONIC MODULES OR ASSEMBLIES

(71) Applicant: Fraunhofer-Gesellschaft zur Foerderung der angewandten Forschung e.V., Muenchen (DE)

(72) Inventors: Yu ZECHUN, Erlangen (DE); Christoph Friedrich BAYER, Erlangen (DE); Andreas SCHLETZ, Erlangen (DE)

(21) Appl. No.: 17/216,815

(22) Filed: Mar. 30, 2021

(30) Foreign Application Priority Data
Mar. 30, 2020 (DE) 10 2020 204 119.9

(51) Int. Cl. H01L 23/00

(52) U.S. Cl. CPC H01L 24/33; H01L 24/03; H01L 24/40; H01L 24/83

(57) ABSTRACT

In a method for connecting components during production of power electronics modules or assemblies, surfaces of the components have a metallic surface layer upon supply, or are furnished therewith, wherein the layer has a surface that is smooth enough to allow direct bonding or is smoothed to obtain a surface that is smooth enough to allow direct bonding. The surface layers of the surfaces that are to be connected are then pressed against each other with a pressure of at least 5 MPa at elevated temperature, so that they are joined to each other, forming a single layer. The method enables simple, rapid connection of even relatively large contact surfaces, which satisfies the high requirements of power electronics modules.

### TECHNICAL FIELD

The invention relates to a method for connecting components during production of power electronics modules or assemblies which in particular include one or more semiconductor elements on a substrate or stacked one on top of the other, and power electronics modules or assemblies which have been manufactured by implementing the method.

Power electronics modules such as are used for example as converters, inverters, transformers, switching power supplies or amplifiers typically include a circuit carrier made for example from a ceramic substrate, on which the semiconductor elements required for the respective application, such as power transistors, diodes or similarly designed semiconductor elements (for example Si-based RC snubbers) are placed and connected electrically. The circuit carrier may also be connected by its rear side to a base plate, which may be constructed as a heat sink in order to cool the module.

Generally, it is also only possible to create one joint between two or more semiconductor elements or one semiconductor element with one or more metallic connection lugs for the power electronics application using the method described in the present patent application.

The individual components of power electronics modules, that is to say particularly the semiconductor elements, the substrate and also electrical connecting elements, must be connected to each other suitably during production of the power electronics module. This connection is subject to exceptional demands due to the high thermal loads during operation of power electronics modules, and also the high currents and voltages produced thereby, which do not occur in other fields of electronics engineering such as microelectronics or integrated circuits. The connecting technologies applied in power electronics engineering should in particular be designed to create expansive contacts on which the surfaces to be connected have surface areas larger than 2 mm×2 mm. At the same time, the tolerances when making the connection should be less than 100 μm. The connections must also be able to sustain high operating temperatures of >200° C.

### RELATED ART

Until now, in the production of power electronics modules the individual components were connected to each other using techniques such as soldering, sintering or adhesive bonding. However, these techniques pose challenges in the connection of wide-bandgap components (SiC, GaN, etc.). When sintering, a sintering paste or sintering film must be applied. When the sintering material is applied, only limited process precision can be maintained. Moreover, layers of sinter can exhibit an undesirable degree of porosity. In addition, the load from electrically conductive particles must be handled meticulously, as such contaminants may be harmful to subsequent processes as well as the operation and service life of power electronics components. The technique of soldering is also associated with very limited process precision and other, similar challenges.

Another known technique which is employed in producing power electronics modules is thermocompression bonding. However, for this connection technique it is necessary to create bumps and bondpads on the surfaces that are to be connected. This in turn leads to difficulties in the precise alignment and/or positioning of the bumps relative to the bondpads.

In US 2019/0047093 A1, as an alternative to a soldering material it is suggested to use a bonding material in the form of a layer of amorphous silver which is applied to each of the surfaces to be connected. The two surfaces are then brought into contact and bonded with each other by heating. This connection can be accomplished without the application of pressure, or by pressing together lightly with a pressure of ≤1 MPa. The connection is based on the hillock growth in the layers of amorphous silver. This document offers no indication as to the suitability of this connecting technique for power electronics. The provision of a layer of amorphous silver requires a thermal pretreatment in which a layer of crystalline silver is first deposited by known methods on the surfaces to be connected, and this is then transformed into an amorphous silver layer on the surface by thermal treatment in an oxygen-rich atmosphere.

The problem addressed by the present invention consists in describing a method for connecting components during the production of power electronics modules and assemblies in various atmospheres, for example air, vacuum or nitrogen, which with simple process management enables the creation of a reliable, durable connection of even relatively large surfaces of >2 mm×2 mm, and which can sustain the demands of power electronics.

### SUMMARY OF THE INVENTION

The problem is solved with the method according to claim 1. Claims 11 and 13 describe a power electronics module or power electronics assembly in which one or more components have been connected to each other using the suggested method. Advantageous variations of the method and of the power electronic module or the power electronics assembly are subject of the dependent claims or are discernible from the following description and exemplary embodiments.

With the suggested method, components are connected to each other during production of power electronics modules or assemblies (for example, semiconductor element stacks, semiconductor element with contacting, etc.) The power electronics module in particular includes one or more semiconductor elements on a substrate, for example a ceramic substrate. The power electronics assemblies may have several semiconductor elements stacked on top of each other, for example. In this context, power electronics modules or the term power electronics is/are understood to mean systems with electrical circuits that are operated with voltages of ≥10 V and/or currents of ≥10 A and have a correspondingly high thermal load. In the method, component surfaces that are to be connected, often having a surface area of at least 2×2 mm², are produced with a metallic surface layer or furnished with such a surface layer, which either has a sufficiently smooth surface to allow direct bonding, or which is smoothed in order to obtain a surface which is smooth enough for direct bonding. The technique of direct bonding is known from semiconductor and microsystems engineering for connecting wafers, for example. In such cases, the roughness of the correspondingly smooth surface preferably has a value of Ra≤0.2 μm (mean roughness index) and/or Rz≤1 μm (averaged roughness depth). The surface layers of the surfaces to be connected are then pressed against each other with a pressure of at least 5 MPa at elevated temperature, so that they are connected to each other, forming a single layer. The elevated temperature is preferably ≥180° C., but this depends on the metallic material used in each case. Ag or a metallic material containing Ag as its main constituent is used particularly advantageously as the material of the surface layer, since this material can be connected by direct bonding at relatively low temperatures. Other materials such as for example Cu, Au, Ti, Pt or Al can be used for the surface layers.

The suggested method may thus be applied successfully without additional sintering pastes or solders, and may be performed very easily and rapidly. In particular, it is suitable for flat contacts having relatively large surfaces ≥2×2 mm² and at the same time allows very close tolerances of <100 μm during connection. The connections created in this way are also stable at operating temperatures >200° C. The method can also be used to connect ultrathin (<20 μm) semiconductor elements to each other, to other semiconductor elements or to the substrate. The method can be carried out inexpensively and enables different materials such as Si, SiC, GaN, GaO, GaAs, AlN or diamond to be connected to each other. The method may also be used to connect different semiconductor materials with electrical conductors, made from Cu or Al, for example. In this way, not only can the semiconductor elements be connected to the substrate, but 3D chip stacks can also be made from a wide variety of semiconductor elements, for example diodes, transistors, capacitors, sensors etc.

Preferably, substrates having low coefficients of thermal expansion such as Si, GaN, SiC, Al2O3, AlN or Si3N4 are used in the manufacture of power electronics modules. The surfaces of these substrates can also be smoothed further, for example by physical and chemical etching methods, mechanical polishing and laser ablation, and a chemically or physically applied metallisation, for example vapour deposited or sputtered metal to enable deposition of the smoothest metallic surface layer possible.

In advantageous variants of the method, one or more of the semiconductor elements are connected to the substrate via the metallic surface layers, and/or connected to each other to form a component stack. The further option exists to use an electrical connecting element in the form of a strip instead of a conventional bonding wire for electrical contacting or to connect the semiconductor elements, wherein such an element is connected to the respective semiconductor elements in accordance with the suggested method. In this context, the corresponding contact surfaces in turn are supplied with or coated with the metallic surface layer, consisting of Ag for example. This enables electrical connections to be made very rapidly and easily during the production of the power electronics modules.

The metallic surface layers used for the connection may also be structured suitably or supplied having been structured previously, before the connection, so that after the connection individual layer regions of the layer formed thereby are electrically insulated from each other by gaps. This enables suitable electrical circuitry to be produced with the aid of the connecting layers.

The surface layers may also be structured or supplied having been structured previously to form recesses and one or more of recesses may be filled with an insulating material before the connection. Preferably, an insulating material is used which the elevated temperature causes to fuse during production of the connection. Insulating material and selection of the temperature for the connection may be tuned to each other, for example also by selecting a correspondingly higher temperature. With the insulating material and the corresponding structuring of the surface layers, it is possible to create a very fine insulation of individual regions of the power electronic module, that is to say an insulation with high resolution. A glass material is used particularly advantageously as the insulating material. A wide range of fusible glasses is available for process temperatures above 400° C. When such glasses—or also other insulating materials—are used, the electrically insulating connection points are bonded materially, for example by fusing, sintering, or also by chemical reaction with appropriate selection of the insulating material.

A corresponding power electronics module including one or more semiconductor components on a substrate, in particular on a ceramic substrate, is characterized in that one or more of the components of the power electronics module are connected to each other by application of the suggested method. The components may be the substrate and one or more semiconductor components, semiconductor components stacked on top of each other, or also electrical connecting elements which are connected to one or more semiconductor components and/or the substrate.

### BRIEF DESCRIPTION OF THE DRAWING

In the following text, the suggested method will be explained again in greater detail with reference to exemplary embodiments and in conjunction with the drawing. In the drawing:

FIG. 1 shows an example of the connection of two ultrathin semiconductor elements to a substrate according to the suggested method;

FIG. 2 shows an example of stacking of two semiconductor diodes according to the suggested method;

FIG. 3 shows an example of the connection of a semiconductor element to a substrate using additional insulating material according to the suggested method;

FIG. 4 shows an example of the electrical connection of a semiconductor element to a contact pad on the substrate via an electrical connecting element according to the suggested method;

FIG. 5 shows examples of stacking MOSFETs on each other (sub-image A) and connection of MOSFETs to a substrate (sub-image B) according to the suggested method;

FIG. 6 shows an example of the connection of MOSFETs to two substrates according to the suggested method;

FIG. 7 shows examples of stacking MOSFETs on and beside a vertical Si-capacitor, and the connection with a substrate according to the suggested method;

FIG. 8 shows an example of an alternative arrangement to the arrangement of FIG. 7;

FIG. 9 shows an example of stacking MOSFETs on a lateral Si-capacitor according to the suggested method; and

FIG. 10 shows an example of an alternative arrangement to the arrangement of FIG. 9.

### WAYS TO IMPLEMENT THE INVENTION

In the suggested method, surfaces of the components of a power electronics module or a power electronics assembly to be connected are joined using the technique of direct metal diffusion bonding. This not only enables semiconductor elements of the power electronics module to be connected to the substrate, but also 3D stacking of the semiconductor elements or element chips on the substrate. This in turn enables innovative circuitry concepts to be created by 3D power integration, which combine excellent high frequency properties with a mechanically rugged, low-loss substrate.

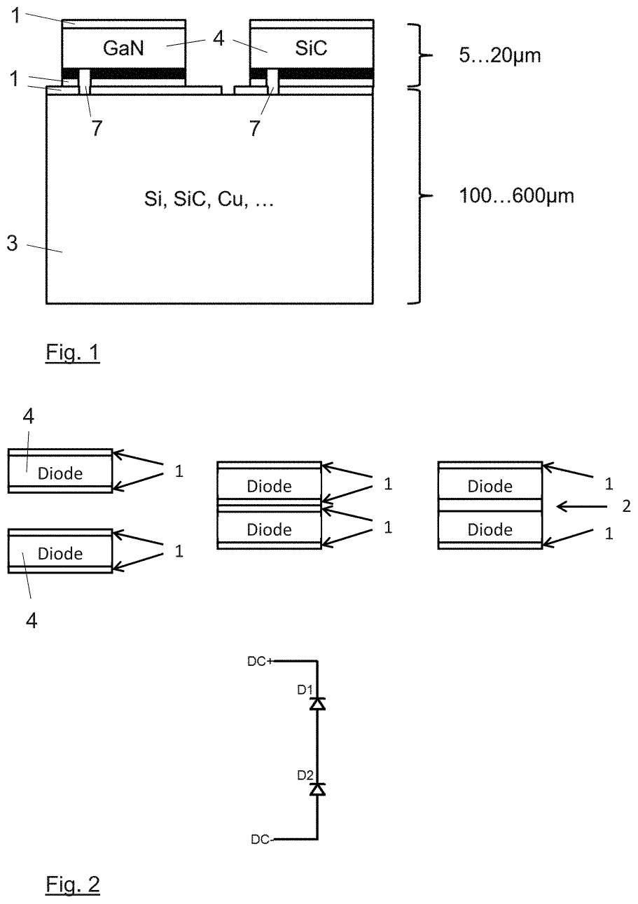

The suggested method also enables the connection of ultrafine wide bandgap elements having a thickness of <20 μm to the substrate, or also to each other or to other semiconductor elements. This is represented schematically in FIG. 1, in which two such ultrathin semiconductor elements 4, in the present case made from GaN and SiC, are connected to the substrate 3 of the power electronics module, made for example from Si, SiC, Cu or another suitable material. For this purpose, a metallic surface layer, in this and the following examples a layer of crystalline Ag 1, is applied to the surface of the substrates 3 and structured for the subsequent function of an electrical circuit or electrical connections. Similarly, an Ag layer 1 is also applied to the underside of the semiconductor element 4. These surface layers are brought into contact with each other, and the respective components 4 are pressed against each the substrate 3 with correspondingly high pressure, in the present examples in a range from >10 to 35 MPa, and at elevated temperature, in the case of Ag layers preferably in the range between 240° C. and 280° C., for about 1 to 15 minutes. In this way, the Ag layers 1 arranged next to each other are joined to form a single connecting layer (not discernible in FIG. 1). In this case, the structuring of the Ag layers 1 formed an insulating gap 7 during the connection, which insulates the individual regions of the connecting layer formed from each other. In the example of FIG. 1, a corresponding Ag layer 1 is also applied to the upper side of the elements 4, which enables either a contacting between these elements during subsequent processing or also a stacking of additional semiconductor elements.

FIG. 2 shows an example of stacking two diodes as semiconductor elements 4 to accomplish a serial connection o of the diodes as represented in the bottom part of the figure. In this example, both sides of the two diodes again have an Ag layer 1 as the metallic surface layer, they are the placed one on top the other and connected to each other by direct bonding through the application of pressure at elevated temperature. In this connection, the two Ag layers 1 lying one on top of the other form a single Ag layer as connecting layer 2, as is suggested in the portion of the figure on the right. Of course, such a stack of two semiconductor elements 4 in power electronic modules can also be made with other semiconductor elements such as transistors or capacitors and also with more than two semiconductor elements 4. The contact surfaces of such semiconductor elements in power electronics modules typically have a surface area of at least 2×2 mm².

In order to insulate individual layer regions of the connecting layer 2 which is created by the connection from each other, additional insulators besides a pure structuring such as in FIG. 1 may also be used, as is represented by way of example in conjunction with FIG. 3. In this example, again the Ag layers 1 are first structured. Then, an insulating material 6 is introduced into corresponding recesses or also locally onto the surface of said layers 1, as is indicated schematically in the left portion of FIG. 3. In this example, a glass material is used as insulating material 6. Then while the two Ag layers 1 are connected to each other by the application of pressure at elevated temperature, the electrically insulating connection points are also bonded with each other materially, thereby forming corresponding insulation in the joint thus created, as may be seen in the portion on the right of FIG. 3. In this context, the material connection is made as a result of the elevated temperature, for example by sintering, by chemical reaction, or in particular—as in this example—by fusing. When a glass material is used as the insulating material 6, the glass material and the temperatures used when making the connection are tuned to each other in such manner that the glass material melts and correspondingly joins with itself in a material bond.

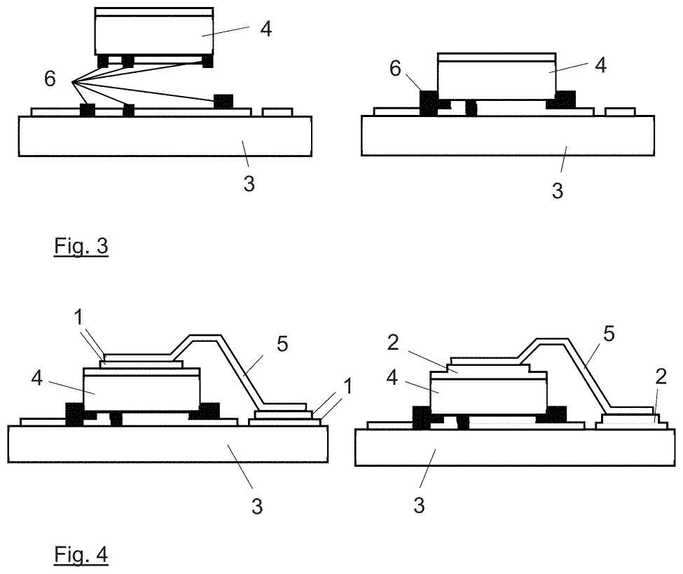

The suggested method also enables the electrical connection of individual regions of the power electronics module via corresponding electrical connecting elements 5, which in this case have the form of strips. In this case too, an Ag layer 1 is applied to the respective contact surfaces as is shown in the left portion of FIG. 4. The corresponding contact surfaces are then joined by the application of pressure at elevated temperature, and form a single, cohesive Ag and connecting layer 2 (compare with the portion of FIG. 4 on the right.

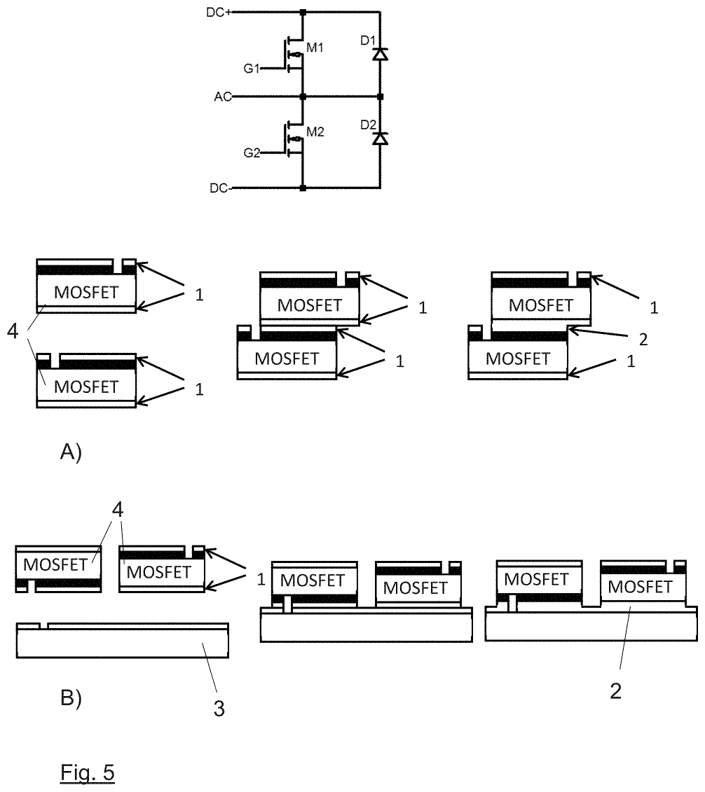

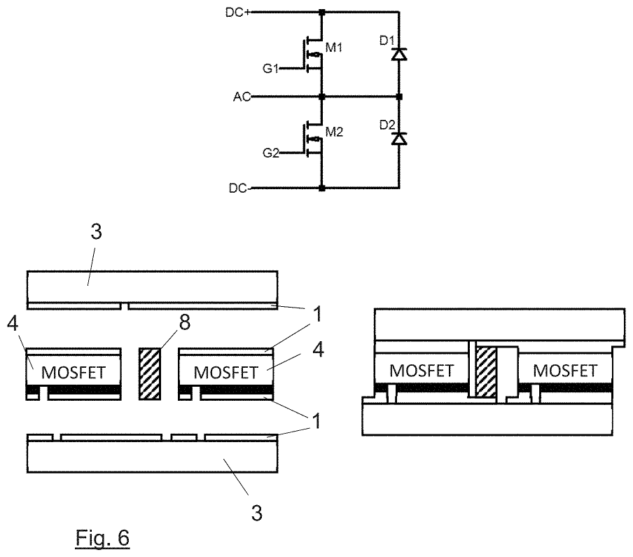

FIGS. 5 and 6 show examples of different ways to create a circuit represented in the top part of FIG. 5A. Accordingly, in the example of FIG. 5A the two MOSFETs as semiconductor elements 4 are stacked one above the other in such a way as to create the circuitry of these transistors as represented in the top part of the figure. In this case, the connection is again made by direct bonding with suitable metallic surface layers, in this example Ag layers 1, which are structured suitably in advance.

FIG. 5B shows an alternative option, in which the two MOSFETs are arranged side by side on the substrate 3 and connected to the substrate 3. FIG. 6 in turn shows an example of a connection in which a further substrate 3 is placed over the two MOSFETs which are arranged side by side on the substrate 3 in order to create the corresponding connection via the Ag layers 1 required for the connection and an additional electrical connecting element 8. In this case, the individual components are again connected by direct meal bonding according to the suggested method.

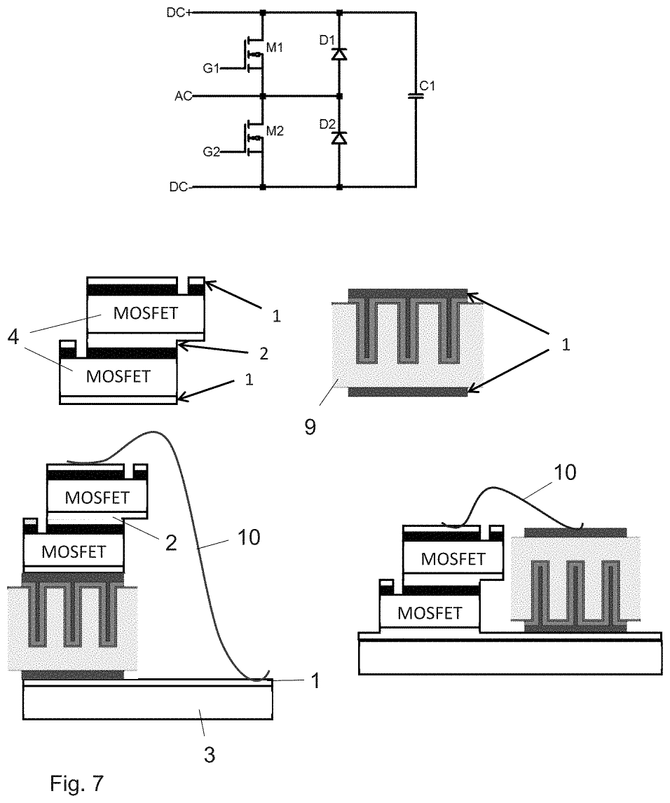

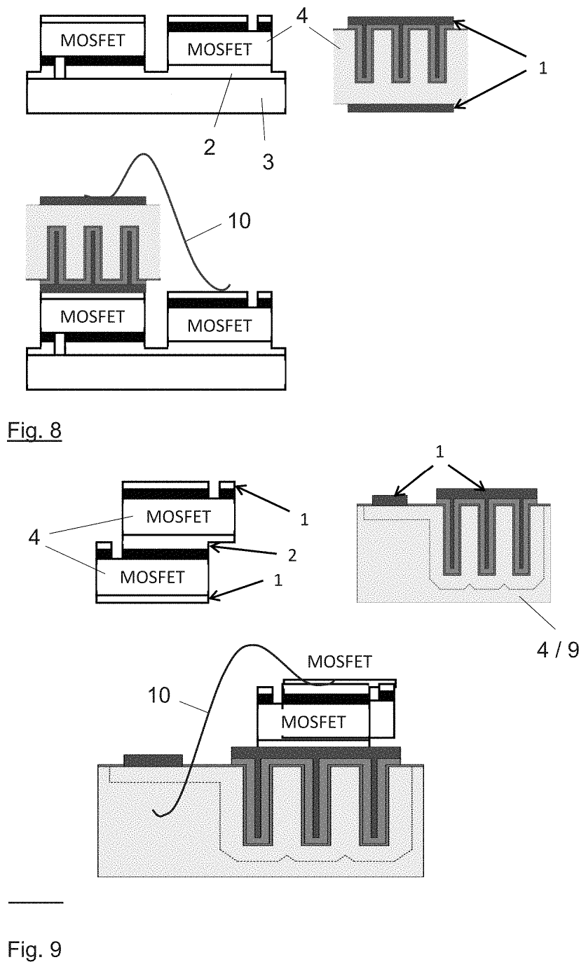

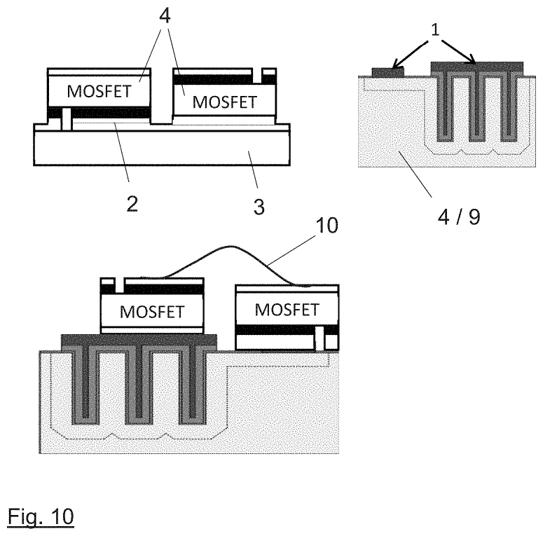

Finally, FIGS. 7 to 10 show a further example in which a circuit with an additional capacitor as illustrated in the top part of FIG. 7 is accomplished. In the example of FIG. 7, the vertical capacitor 9 and the two MOSFETs are stacked one on top of the other on the substrate. The electrical connection of the top MOSFET with the metallisation on the substrate 3 may be realised either via a bonding wire 10 also in similar manner to that shown in FIG. 4. The same applies for the second alternative shown in FIG. 7, in which the vertical capacitor 9 is arranged beside the stack of two MOSFETs on the substrate 3. FIG. 8 shows a further alternative, in which the two MOSFETs are arranged side by side on the substrate 3 and the vertical capacitor 9 is stacked on top of one of the two MOSFETs.

Whereas in FIGS. 7 and 8 a vertical Si capacitor was used, FIGS. 9 and 10 illustrate a variant with a lateral Si capacitor 9, on which the two MOSFETs in FIG. 9 are stacked. In contrast, FIG. 10 shows an arrangement of the two MOSFETs side by side on the capacitor.

### LIST OF REFERENCE NUMERALS

1 Ag layer
2 Connecting layer
3 Substrate
4 Semiconductor element
5 Electrical connecting element
6 Insulating material
7 Insulating gap
8 Electrical connecting element
9 Capacitor
10 Bonding wire

1. Method for connecting components during production of power electronics modules or assemblies which in particular include one or more semiconductor elements (4) on a substrate (3) or on each other,
in which surfaces of the components that are to be connected are supplied with an existing metallic surface layer (1) or furnished therewith, which layer has a surface that is sufficiently smooth to allow direct bonding or that is polished to obtain a surface that is sufficiently smooth to allow direct bonding, and the surface layers (1) of the surfaces to be connected are pressed against each other with a pressure of at least 5 MPa at elevated temperature so that they are connected to each other, forming a single layer (2).

2. Method according to claim 1,
characterized in that
the surface layers (1) of the surfaces to be connected are pressed against each other with a pressure of >10 MPa.

3. Method according to claim 1,
characterized in that
the surfaces of the components that are to be connected are provided with an existing surface layer (1) of Ag or a metallic material containing Ag as its major constituent, or are coated with such a layer as said metallic surface layer (1).

4. Method according to claim 1,
characterized in that
one or more of the semiconductor elements (4) as components are connected to the substrate (3).

5. Method according to claim 1,
characterized in that
several of the semiconductor elements (4) as components are connected to each other, forming a component stack.

6. Method according to claim 1,
characterized in that
one or more of the semiconductor elements (4) as components are connected with one or more electrical connecting elements (5) in the form of strips.

7. Method according to claim 1,
characterized in that
the surface layers (1) are structured before the connection, or are already structured when supplied such that individual layer regions of the layer (2) formed are electrically insulated from each other by gaps (7) after the connection.

8. Method according to claim 1,
characterized in that
the surface layers (1) are structured before the connection, or are already structured when supplied such that recesses are formed, wherein an insulating material (6) is introduced into one or more of the recesses in the surface layers (1) before the connection.

9. Method according to claim 8,
characterized in that
the insulating material (6) and the elevated temperature are selected such that the insulating material (6) melts during the connection of the surface layers (1) due to the elevated temperature.

10. Method according to claim 8,
characterized in that
a glass material is used as the insulating material (6).

11. Power electronics module including one or more semiconductor elements (4) on a substrate (3), wherein one or more components of the power electronics module is/are connected to each other by the method according to claim 1.

12. Power electronics module according to claim 11,
characterized in that
one or more of the semiconductor elements (4) as components are connected to the substrate (3) by the method.

13. Power electronics assembly including one or more semiconductor elements (4), wherein one or more components of the power electronics assembly are connected to each other by the method according to claim 1.

14. Power electronics module or power electronics assembly according to claim 11,
characterized in that
several of the semiconductor elements (4) as components are connected to each other by the method, forming a component stack.

15. Power electronics module or power electronic assembly according to claim 11,
characterized in that
one or more of the semiconductor elements (4) as components are connected to one or more electrical connecting elements (5) designed in the form of strips by the method.

16. Power electronics assembly according to claim 13,
characterized in that
several of the semiconductor elements (4) as components are connected to each other by the method, forming a component stack.

17. Power electronics assembly according to claim 13,
characterized in that
one or more of the semiconductor elements (4) as components are connected to one or more electrical connecting elements (5) designed in the form of strips by the method.
